(19) United States
(12) Patent Application Publication
(10) Pub. No.: US 2015/0364901 A1
(43) Pub. Date: Dec. 17, 2015

(54) LENS MOUNTING ARRANGEMENTS FOR HIGH-POWER LASER SYSTEMS

(71) Applicants: Michael Deutsch, Wilmington, MA (US); Daqing Wang, Wilmington, MA (US)

(72) Inventors: Michael Deutsch, Wilmington, MA (US); Daqing Wang, Wilmington, MA (US)

(21) Appl. No.: 14/736,599

(22) Filed: Jun. 11, 2015

Related U.S. Application Data
(60) Provisional application No. 62/012,332, filed on Jun. 14, 2014.

(51) Int. Cl. H01S 5/40; H01S 5/042; H01S 5/187; H01S 5/183; H01S 5/022; H01S 5/42

(52) U.S. Cl. CPC H01S 5/4012; H01S 5/4025; H01S 5/02252; H01S 5/423; H01S 5/187; H01S 5/18361; H01S 5/0425; H01S 5/4087

(57) ABSTRACT

In various embodiments, a laser apparatus includes top and bottom electrode mounts, a beam emitter between the electrode mounts, a fast axis collimation lens, an optical rotator, and a lens holder or lens mount positioning the lens and the optical rotator to intercept one or more beams emitted by the beam emitter.

### RELATED APPLICATIONS

This application claims the benefit of and priority to U.S. Provisional Patent Application No. 62/012,332, filed Jun. 14, 2014, the entire disclosure of which is hereby incorporated herein by reference.

### TECHNICAL FIELD

In various embodiments, the present invention relates to laser emitters, specifically schemes for mounting lenses on such emitters.

### BACKGROUND

High-power laser systems are utilized for a host of different applications, such as welding, cutting, drilling, and materials processing. Such laser systems typically include a laser emitter, the laser light from which is coupled into an optical fiber (or simply a “fiber”), and an optical system that focuses the laser light from the fiber onto the workpiece to be processed. Wavelength beam combining (WBC) is a technique for scaling the output power and brightness from laser diodes, laser diode bars, stacks of diode bars, or other lasers arranged in one- or two-dimensional array. WBC methods have been developed to combine beams along one or both dimensions of an array of emitters. Typical WBC systems include a plurality of emitters, such as one or more diode bars, that are combined using a dispersive element to form a multi-wavelength beam. Each emitter in the WBC system individually resonates, and is stabilized through wavelength-specific feedback from a common partially reflecting output coupler that is filtered by the dispersive element along a beam-combining dimension. Exemplary WBC systems are detailed in U.S. Pat. No. 6,192,062, filed on Feb. 4, 2000, U.S. Pat. No. 6,208,679, filed on Sep. 8, 1998, U.S. Pat. No. 8,670,180, filed on Aug. 25, 2011, and U.S. Pat. No. 8,559,107, filed on Mar. 7, 2011, the entire disclosure of each of which is incorporated by reference herein.

While techniques such as WBC have succeeded in producing laser-based systems for a wide variety of applications, challenges related to the establishment and focusing of individual resonating beams in WBC systems remain. For example, during start-up of WBC systems from a non-emitting or “off” state (i.e., a “cold start”), various lenses for the collimation and/or focusing of emitter beams may experience deleterious motion and/or deformation due to, for example, differences in the coefficient of thermal expansion between the lenses and other (e.g., metallic) components. Such lens motion may cause, for example, the resonating beam to grow side lobes in the far field that result in degradation of fiber coupling of the beam. Thus, there is a need for improved schemes for lens mounting and attachment for high-power laser systems.

### SUMMARY

In accordance with embodiments of the present invention, laser assemblies feature beam emitters (e.g., diodes, diode bars, or arrays thereof), as well as lens holders or mounts that position lenses and/or optical rotators to intercept the beams from the beam emitters while minimizing or substantially eliminating deleterious deformation due to thermal mismatch between the electrode mount(s) of the beam emitter and the lens holder or mount. Such arrangements beneficially reduce or minimize optical abnormalities resulting from such deformation, particularly during the initial start-up of the laser assembly (as opposed to steady-state operation of the assembly once the temperatures of the various components have increased to their operating temperatures). Specifically, the lens mount or holder may either be mechanically coupled only to the bottom electrode mount of the beam emitter (rather than only to the top electrode mount), or it may be mechanically coupled to both top and bottom electrode mounts via one or more mounting disks. The mounting disks may be utilized to mount a lens (e.g., a fast axis collimation (FAC) lens) such that the centroid of the bond line (and/or the lens) is substantially along the neutral axis between top and bottom electrode mounts (i.e., substantially aligned with the beam emitter therebetween). The lens holder or mount may be a one-piece (i.e., unitary) structure or may be composed of multiple parts that are coupled together (e.g., via an adhesive such as epoxy).

As utilized herein, materials with a high thermal conductivity, or “thermally conductive materials,” have a thermal conductivity of at least 100 watts per meter per Kelvin (W·m⁻¹·K⁻¹), at least 170 W·m⁻¹·K⁻¹, or even at least 300 W·m⁻¹K⁻¹. As utilized herein, materials with a high electrical conductivity, or “electrically conductive materials,” have an electrical conductivity, e.g., at 20° C., of at least 1×10⁵ siemens per meter (S/m), at least 1×10⁶ S/m, or even at least 1×10⁷ S/m. As utilized herein, materials with a high electrical resistivity, or “electrically insulating materials,” have an electrical resistivity of at least ×10⁸ ohm·meter (Ω.m), at least ×10¹⁰ Ω·m, or even at least ×10¹² Ω·m.

Embodiments of the invention may be utilized in conjunction with techniques to reduce, correct, and/or ameliorate the impact of smile in beam emitters such as diode bars that are described in U.S. patent application Ser. No. 14/476,544, filed on Sep. 3, 2014, the entire disclosure of which is incorporated by reference herein. Embodiments of the invention may be utilized in conjunction with thermal management techniques and structures that are described in U.S. patent application Ser. No. 14/666,438, filed on Mar. 24, 2015, the entire disclosure of which is incorporated by reference herein.

Laser diodes utilizing mounting schemes in accordance with embodiments of the present invention may be utilized in WBC systems to form high brightness, low beam parameter product (BPP) laser systems. The BPP is the product of the laser beam's divergence angle (half-angle) and the radius of the beam at its narrowest point (i.e., the beam waist, the minimum spot size). The BPP quantifies the quality of the laser beam and how well it can be focused to a small spot, and is typically expressed in units of millimeter-milliradians (mm-mrad). A Gaussian beam has the lowest possible BPP, given by the wavelength of the laser light divided by pi. The ratio of the BPP of an actual beam to that of an ideal Gaussian beam at the same wavelength is denoted M², or the “beam quality factor,” which is a wavelength-independent measure of beam quality, with the “best” quality corresponding to the “lowest” beam quality factor of 1.

As known to those of skill in the art, lasers are generally defined as devices that generate visible or invisible light through stimulated emission of light. Lasers generally have properties that make them useful in a variety of applications, as mentioned above. Common laser types include semiconductor lasers, solid-state lasers, fiber lasers, and gas lasers. Semiconductor lasers (mostly laser diodes) may be electrically or optically pumped and generally efficiently generate very high output powers often at the expense of poor beam quality. Semiconductor lasers may produce low power with good spatial properties for application in, e.g., optical disc players. Yet other semiconductor lasers may be suitable for producing high pulse rate, low power pulses (e.g., for telecommunications applications). Special types of semiconductor lasers include quantum cascade lasers (for mid-infrared light) and surface-emitting semiconductor lasers (VCSELs and VECSELs), the latter also being suitable for pulse generation with high powers.

Solid-state lasers may be based on ion-doped crystals or glasses (e.g., doped insulator lasers) and may pumped with discharge lamps or laser diodes for generating high output power. Alternatively solid-state lasers may produce low power output with very high beam quality, spectral purity and/or stability (e.g. for measurement purposes). Some solid-state lasers may produce ultra-short pulses with picosecond or femtosecond durations. Common gain media for use with solid state lasers include: Nd:YAG, Nd:YVO₄, Nd:YLF, Nd:glass, Yb:YAG, Yb:glass, Ti:sapphire, Cr:YAG, and Cr:LiSAF.

Fiber lasers may be based on optical glass fibers which are doped with some laser-active ions in the fiber core. Fiber lasers may achieve extremely high output powers (up to kilowatts) with high beam quality. Narrow line width operation and the like may also be supported by fiber lasers. Gas lasers may include helium-neon lasers, CO₂ lasers, argon ion lasers, and the like may be based on gases which are typically excited with electrical discharges. Frequently used gases include CO₂, argon, krypton, and gas mixtures such as helium-neon. In addition, excimer lasers may be based on any of ArF, KrF, XeF, and F₂. Other less common laser types include chemical and nuclear pumped lasers, free electron lasers, and X-ray lasers.

A laser diode, such as a laser diode described in the following general description may be used in association with embodiments of the innovations described herein. A laser diode is generally based on a simple diode structure that supports the emission of photons (light). However, to improve efficiency, power, beam quality, brightness, tunability, and the like, this simple structure is generally modified to provide a variety of many practical types of laser diodes. Laser diode types include small edge-emitting varieties that generate from a few milliwatts up to roughly half a watt of output power in a beam with high beam quality. Structural types of diode lasers include double hetero-structure lasers that include a layer of low bandgap material sandwiched between two high bandgap layers; quantum well lasers that include a very thin middle layer (quantum well layer) resulting in high efficiency and quantization of the laser's energy; multiple quantum well lasers that include more than one quantum well layer improve gain characteristics; quantum wire or quantum sea (dots) lasers replace the middle layer with a wire or dots that produce higher efficiency quantum well lasers; quantum cascade lasers that enable laser action at relatively long wavelengths that may be tuned by altering the thickness of the quantum layer; separate confinement heterostructure lasers, which are the most common commercial laser diode and include another two layers above and below the quantum well layer to efficiently confine the light produced; distributed feedback lasers, which are commonly used in demanding optical communication applications and include an integrated diffraction grating that facilitates generating a stable wavelength set during manufacturing by reflecting a single wavelength back to the gain region; vertical-cavity surface-emitting lasers (VCSELs), which have a different structure that other laser diodes in that light is emitted from its surface rather than from its edge; and vertical-external-cavity surface-emitting-laser (VECSELs) and external-cavity diode lasers, which are tunable lasers that use mainly double heterostructure diodes and include gratings or multiple-prism grating configurations. External-cavity diode lasers are often wavelength-tunable and exhibit a small emission line width. Laser diode types also include a variety of high power diode-based lasers including: broad area lasers that are characterized by multi-mode diodes with oblong output facets and generally have poor beam quality but generate a few watts of power; tapered lasers that are characterized by astigmatic mode diodes with tapered output facets that exhibit improved beam quality and brightness when compared to broad area lasers; ridge waveguide lasers that are characterized by elliptical mode diodes with oval output facets; and slab-coupled optical waveguide lasers (SCOWL) that are characterized by circular mode diodes with output facets and may generate watt-level output in a diffraction-limited beam with nearly a circular profile.

Laser diode arrays, bars and/or stacks, such as those described in the following general description may be used in association with embodiments of the innovations described herein. Laser diodes may be packaged individually or in groups, generally in one-dimensional rows/arrays (diode bars) or two dimensional arrays (diode-bar stacks). A diode array stack is generally a vertical stack of diode bars. Laser diode bars or arrays generally achieve substantially higher power, and cost effectiveness than an equivalent single broad area diode. High-power diode bars generally contain an array of broad-area emitters, generating tens of watts with relatively poor beam quality; despite the higher power, the brightness is often lower than that of a broad area laser diode. High-power diode bars may be stacked to produce high-power stacked diode bars for generation of extremely high powers of hundreds or thousands of watts. Laser diode arrays may be configured to emit a beam into free space or into a fiber. Fiber-coupled diode-laser arrays may be conveniently used as a pumping source for fiber lasers and fiber amplifiers.

A diode-laser bar is a type of semiconductor laser containing a one-dimensional array of broad-area emitters or alternatively containing sub arrays containing, e.g., 10-20 narrow stripe emitters. A broad-area diode bar typically contains, for example, 19-49 emitters, each having dimensions on the order of, e.g., 1 μm×100 μm. The beam quality along the 1 μm dimension or fast-axis is typically diffraction-limited. The beam quality along the 100 μm dimension or slow-axis or array dimension is typically many times diffraction-limited. Typically, a diode bar for commercial applications has a laser resonator length of the order of 1 to 4 mm, is about 10 mm wide and generates tens of watts of output power. Most diode bars operate in the wavelength region from 780 to 1070 nm, with the wavelengths of 808 nm (for pumping neodymium lasers) and 940 nm (for pumping Yb:YAG) being most prominent. The wavelength range of 915-976 nm is used for pumping erbium-doped or ytterbium-doped high-power fiber lasers and amplifiers.

A property of diode bars that is usually addressed is the output spatial beam profile. For most applications beam conditioning optics are needed. Significant efforts are therefore often required for conditioning the output of a diode bar or diode stack. Conditioning techniques include using aspherical lenses for collimating the beams while preserving the beam quality. Micro optic fast axis collimators may be used to collimate the output beam along the fast-axis. Array of aspherical cylindrical lenses are often used for collimation of each laser element along the array or slow-axis. To achieve beams with approximately circular beam waist a special beam shaper for symmetrization of the beam quality of each diode bar or array can be applied. A degrading property of diode bars is the “smile”—a slight bend of the planar nature of the connected emitters. Smile errors may have detrimental effects on the ability to focus beams from diode bars. Another degrading property is collimation error of the slow and fast-axis. For example, a twisting of the fast-axis collimation lens results in an effective smile. This has detrimental effects on the ability to focus. In stacks, “pointing” error of each bar is often the most dominant effect. Pointing error is a collimation error and is the result of the array or bar that is offset from the fast-axis lens. An offset of 1 μm is the same as the whole array having a smile of 1 μm.

Diode bars and diode arrays overcome limitations of very broad single emitters, such as amplified spontaneous emission or parasitic lasing in the transverse direction or filament formation. Diode arrays may also be operated with a more stable mode profile, because each emitter produces its own beam. Techniques which exploit some degree of coherent coupling of neighbored emitters may result in better beam quality. Such techniques may be included in the fabrication of the diode bars while others may involve external cavities. Another benefit of diode arrays is that the array geometry makes diode bars and arrays very suitable for coherent or spectral beam combining to obtain a much higher beam quality.

In addition to raw bar or array offerings, diode arrays are available in fiber-coupled form because this often makes it much easier to utilize each emitter's output and to mount the diode bars so that cooling of the diodes occurs some distance from the place where the light is used. Usually, the light is coupled into a single multimode fiber, using either a simple fast-axis collimator without beam conditioning in the slow-axis direction, or a more complex beam shaper to better preserve the brightness. It is also possible to launch the beamlets from the emitters into a fiber bundle (with one fiber per emitter). Emission bandwidth of a diode bar or diode array is an important consideration for some applications. Optical feedback (e.g. from volume Bragg grating) can significantly improve wavelength tolerance and emission bandwidth. In addition, bandwidth and exact center wavelength may also be important for spectral beam combining

A diode stack is simply an arrangement of multiple diode bars that can deliver very high output power. Also called diode laser stack, multi-bar module, or two-dimensional laser array, the most common diode stack arrangement is that of a vertical stack which is effectively a two-dimensional array of edge emitters. Such a stack may be fabricated by attaching diode bars to thin heat sinks and stacking these assemblies so as to obtain a periodic array of diode bars and heat sinks There are also horizontal diode stacks, and two-dimensional stacks. For the high beam quality, the diode bars generally should be as close to each other as possible. On the other hand, efficient cooling requires some minimum thickness of the heat sinks mounted between the bars. This tradeoff of diode bar spacing results in beam quality of a diode stack in the vertical direction (and subsequently its brightness) is much lower than that of a single diode bar. There are, however, several techniques for significantly mitigating this problem, e.g., by spatial interleaving of the outputs of different diode stacks, by polarization coupling, or by wavelength multiplexing. Various types of high-power beam shapers and related devices have been developed for such purposes. Diode stacks may provide extremely high output powers (e.g. hundreds or thousands of watts).

Embodiments of the present invention couple the one or more input laser beams into an optical fiber. In various embodiments, the optical fiber has multiple cladding layers surrounding a single core, multiple discrete core regions (or “cores”) within a single cladding layer, or multiple cores surrounded by multiple cladding layers.

Herein, “optical elements” may refer to any of lenses, mirrors, prisms, gratings, and the like, which redirect, reflect, bend, or in any other manner optically manipulate electromagnetic radiation. Herein, beam emitters, emitters, or laser emitters, or lasers include any electromagnetic beam-generating device such as semiconductor elements, which generate an electromagnetic beam, but may or may not be self-resonating. These also include fiber lasers, disk lasers, non-solid state lasers, etc. Generally, each emitter includes a back reflective surface, at least one optical gain medium, and a front reflective surface. The optical gain medium increases the gain of electromagnetic radiation that is not limited to any particular portion of the electromagnetic spectrum, but that may be visible, infrared, and/or ultraviolet light. An emitter may include or consist essentially of multiple beam emitters such as a diode bar configured to emit multiple beams. The input beams received in the embodiments herein may be single-wavelength or multi-wavelength beams combined using various techniques known in the art. In addition, references to “lasers,” “laser emitters,” or “beam emitters” herein include not only single-diode lasers, but also diode bars, laser arrays, diode bar arrays, and single or arrays of vertical cavity surface-emitting lasers (VCSELs).

In an aspect, embodiments of the invention feature a laser assembly that includes or consists essentially of a beam emitter, a bottom electrode mount, a lens mount, a fast axis collimation (FAC) lens, and an optical rotator. The beam emitter has top and bottom opposed surfaces and an emission surface at least partially spanning the top and bottom surfaces. The laser assembly may include a top electrode mount that is disposed above the top surface of the beam emitter. The bottom electrode mount is disposed below the bottom surface of the beam emitter. The lens mount is mechanically coupled to the bottom electrode mount. The lens mount may not be mechanically connected to the top electrode mount or to the beam emitter (i.e., the lens mount may only be mechanically connected to the bottom electrode mount). At least a portion of the bottom electrode mount may extend laterally beyond the emission surface of the beam emitter. The bottom electrode mount may be mechanically coupled to a substrate and/or to a heat sink. The FAC lens is disposed on the lens mount and positioned to (i) receive one or more beams emitted by the beam emitter, (ii) collimate the one or more beams, and (iii) transmit the one or more collimated beams. The optical rotator is disposed on the lens mount and positioned to (i) receive the one or more collimated beams, (ii) rotate the received one or more collimated beams, and (iii) transmit the one or more rotated beams.

Embodiments of the invention may include one or more of the following in any of a variety of combinations. The top electrode mount may be electrically insulated from the bottom electrode mount. The top electrode mount and/or the bottom electrode mount may include or consist essentially of copper, silver, and/or gold. The top electrode mount and/or the bottom electrode mount may be highly electrically and/or thermally conductive. The lens mount may be electrically insulating. The beam emitter may emit (and/or be configured to emit) a plurality of beams. The lens mount may include, consist essentially, or consist of a unitary structure supporting the FAC lens and the optical rotator. The lens mount may include, consist essentially, or consist of a plurality of discrete sections that are mechanically coupled together. The lens mount may include, consist essentially, or consist of (i) a first section supporting the FAC lens, and (ii) mechanically coupled to the first section, a second section supporting the optical rotator. A coefficient of thermal expansion of the lens mount may be approximately equal to a coefficient of thermal expansion of the FAC lens and/or to a coefficient of thermal expansion of the optical rotator. The lens mount may be mechanically coupled to the bottom electrode mount via an adhesive (e.g., epoxy). The FAC lens and/or the optical rotator may be mechanically coupled to the lens mount via an adhesive (e.g., epoxy).

In another aspect, embodiments of the invention feature a laser assembly that includes or consists essentially of a beam emitter, a bottom electrode mount, a lens mount, a fast axis collimation (FAC) lens, an optical rotator, focusing optics, a dispersive element, and a partially reflective output coupler. The beam emitter has top and bottom opposed surfaces and an emission surface at least partially spanning the top and bottom surfaces. The beam emitter may be configured to emit a plurality of beams. The bottom electrode mount is disposed below the bottom surface of the beam emitter. The laser assembly may include a top electrode mount disposed above the top surface of the beam emitter. The lens mount is mechanically coupled to the bottom electrode mount. The lens mount may not be mechanically connected to the top electrode mount or to the beam emitter (i.e., the lens mount may only be mechanically connected to the bottom electrode mount). At least a portion of the bottom electrode mount may extend laterally beyond the emission surface of the beam emitter. The bottom electrode mount may be mechanically coupled to a substrate and/or to a heat sink. The FAC lens is disposed on the lens mount and positioned to (i) receive the plurality of beams emitted by the beam emitter, (ii) collimate the plurality of beams, and (iii) transmit the collimated beams. The optical rotator is disposed on the lens mount and positioned to (i) receive the collimated beams, (ii) rotate the received collimated beams, and (iii) transmit the rotated beams. The focusing optics are optically downstream of the optical rotator. The focusing optics focus the rotated beams onto a dispersive element. The dispersive element is optically downstream of the focusing optics. The dispersive element receives and disperses the received focused beams. The partially reflective output coupler is optically downstream of the dispersive element. The partially reflective output coupler is positioned and/or configured to receive the dispersed beams, transmit a portion of the dispersed beams therethrough as a multi-wavelength output beam, and reflect a second portion of the dispersed beams back toward the dispersive element.

Embodiments of the invention may include one or more of the following in any of a variety of combinations. The top electrode mount may be electrically insulated from the bottom electrode mount. The top electrode mount and/or the bottom electrode mount may include or consist essentially of copper, silver, and/or gold. The top electrode mount and/or the bottom electrode mount may be highly electrically and/or thermally conductive. The lens mount may be electrically insulating. The dispersive element may include or consist essentially of a diffraction grating (e.g., a transmissive diffraction grating or a reflective diffraction grating).

In another aspect, embodiments of the invention feature a laser assembly that includes or consists essentially of a beam emitter, a top electrode mount, a bottom electrode mount, a plurality of mounting disks, a lens holder, a fast axis collimation (FAC) lens, and an optical rotator. The beam emitter has top and bottom opposed surfaces and (ii) an emission surface at least partially spanning the top and bottom surfaces. The top electrode mount is disposed above the top surface of the beam emitter. The bottom electrode mount is disposed below the bottom surface of the beam emitter. Each mounting disk is mechanically coupled to both the top electrode mount and the bottom electrode mount. The lens holder defines a slot therethrough. The lens holder is mechanically coupled to the mounting disks such that the slot is substantially aligned with the emission surface of the beam emitter. The FAC lens is supported by (and/or disposed on) the lens holder and positioned to (i) receive one or more beams emitted by the beam emitter, (ii) collimate the one or more beams, and (iii) transmit the one or more collimated beams. The optical rotator is supported by (and/or disposed on) the lens holder and positioned to (i) receive the one or more collimated beams, (ii) rotate the received one or more collimated beams, and (iii) transmit the one or more rotated beams.

Embodiments of the invention may include one or more of the following in any of a variety of combinations. The top electrode mount may be electrically insulated from the bottom electrode mount. The top electrode mount and/or the bottom electrode mount may include or consist essentially of copper, silver, and/or gold. The top electrode mount and/or the bottom electrode mount may be highly electrically and/or thermally conductive. The lens holder may be electrically insulating. The lens holder may have a first surface facing the emission surface of the beam emitter and a second surface opposite the first surface (i.e., facing away from the emission surface of the beam emitter). The first surface of the lens holder may define one or more grooves therewithin. At least a portion of the FAC lens may be disposed within the groove. The optical rotator may be disposed proximate the second surface of the lens holder. The FAC lens may be disposed proximate the first surface of the lens holder and the optical rotator may be disposed proximate the second surface of the lens holder. The beam emitter may emit (and/or be configured to emit) a plurality of beams. A coefficient of thermal expansion of the lens holder may be approximately equal to a coefficient of thermal expansion of the FAC lens and/or to a coefficient of thermal expansion of the optical rotator. The mounting disks may be mechanically coupled to the top electrode mount and to the bottom electrode mount via an adhesive (e.g., epoxy). The FAC lens and/or the optical rotator may be mechanically coupled to the lens holder via an adhesive (e.g., epoxy). The FAC lens may be supported between the lens holder and the emission surface of the beam emitter without being mechanically coupled to the lens holder or to the emission surface.

In another aspect, embodiments of the invention feature a laser assembly that includes or consists essentially of a beam emitter, a top electrode mount, a bottom electrode mount, a plurality of mounting disks, a lens holder, a fast axis collimation (FAC) lens, an optical rotator, focusing optics, a dispersive element, and a partially reflective output coupler. The beam emitter has top and bottom opposed surfaces and (ii) an emission surface at least partially spanning the top and bottom surfaces. The top electrode mount is disposed above the top surface of the beam emitter. The bottom electrode mount is disposed below the bottom surface of the beam emitter. Each mounting disk is mechanically coupled to both the top electrode mount and the bottom electrode mount. The lens holder defines a slot therethrough. The lens holder is mechanically coupled to the mounting disks such that the slot is substantially aligned with the emission surface of the beam emitter. The FAC lens is supported by (and/or disposed on) the lens holder and positioned to (i) receive one or more beams emitted by the beam emitter, (ii) collimate the one or more beams, and (iii) transmit the one or more collimated beams. The optical rotator is supported by (and/or disposed on) the lens holder and positioned to (i) receive the one or more collimated beams, (ii) rotate the received one or more collimated beams, and (iii) transmit the one or more rotated beams. The focusing optics are optically downstream of the optical rotator. The focusing optics focus the rotated beams onto a dispersive element. The dispersive element is optically downstream of the focusing optics. The dispersive element receives and disperses the received focused beams. The partially reflective output coupler is optically downstream of the dispersive element. The partially reflective output coupler is positioned and/or configured to receive the dispersed beams, transmit a portion of the dispersed beams therethrough as a multi-wavelength output beam, and reflect a second portion of the dispersed beams back toward the dispersive element.

Embodiments of the invention may include one or more of the following in any of a variety of combinations. The top electrode mount may be electrically insulated from the bottom electrode mount. The top electrode mount and/or the bottom electrode mount may include or consist essentially of copper, silver, and/or gold. The top electrode mount and/or the bottom electrode mount may be highly electrically and/or thermally conductive. The lens holder may be electrically insulating. The dispersive element may include or consist essentially of a diffraction grating (e.g., a transmissive diffraction grating or a reflective diffraction grating).

These and other objects, along with advantages and features of the present invention herein disclosed, will become more apparent through reference to the following description, the accompanying drawings, and the claims. Furthermore, it is to be understood that the features of the various embodiments described herein are not mutually exclusive and may exist in various combinations and permutations. As used herein, the terms “substantially” and “approximately” mean±10%, and in some embodiments, ±5%. The term “consists essentially of” means excluding other materials that contribute to function, unless otherwise defined herein. Nonetheless, such other materials may be present, collectively or individually, in trace amounts. Herein, the terms “radiation” and “light” are utilized interchangeably unless otherwise indicated. Herein, “downstream” or “optically downstream,” is utilized to indicate the relative placement of a second element that a light beam strikes after encountering a first element, the first element being “upstream,” or “optically upstream” of the second element.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIG. 1A is a perspective view of a laser assembly in accordance with embodiments of the invention;

FIG. 1B is a magnified view of a portion of the laser assembly of FIG. 1A;

FIG. 1C is a side view of the laser assembly of FIG. 1A;

FIG. 1D is a magnified view of a portion of the laser assembly of FIG. 1C;

FIG. 2A is a perspective view of a laser assembly in accordance with embodiments of the invention;

FIG. 2B is a magnified view of a portion of the laser assembly of FIG. 2A;

FIG. 2C is a side view of the laser assembly of FIG. 2A;

FIG. 2D is a magnified view of a portion of the laser assembly of FIG. 2C;

FIGS. 3A and 3B are exploded perspective views of a laser assembly in accordance with embodiments of the invention;

FIG. 3C is a perspective view of the assembled laser assembly of FIGS. 3A and 3B;

FIG. 3D is a magnified view of a portion of the laser assembly of FIG. 3C;

FIG. 3E is a side view of the laser assembly of FIG. 3C;

FIG. 3F is a magnified view of a portion of the laser assembly of FIG. 3E with mounting disks removed for clarity;

FIG. 3G is a magnified view of a portion of the laser assembly of FIG. 3E; and

FIG. 4 is a schematic view of a wavelength beam combining laser system incorporating a laser assembly in accordance with embodiments of the invention.

### DETAILED DESCRIPTION

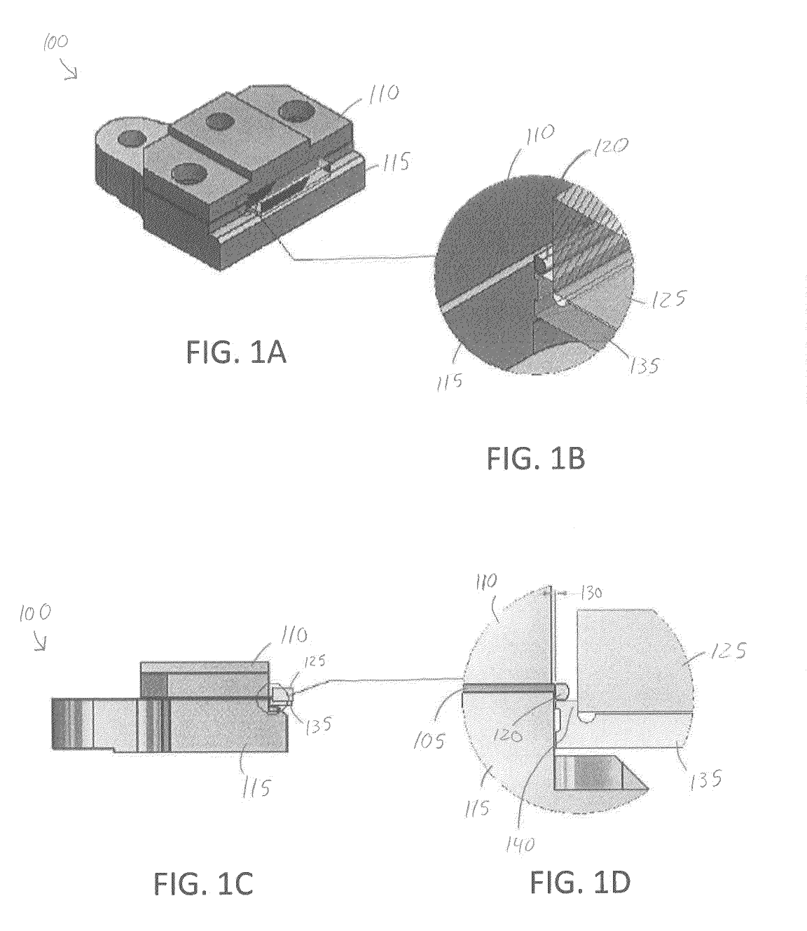

FIGS. 1A-1D depict an exemplary laser assembly 100 in accordance with embodiments of the present invention. As shown, the laser assembly 100 includes a beam emitter 105 sandwiched between a top electrode mount 110 and a bottom electrode mount 115. The beam emitter 105 may include or consist essentially of, e.g., a laser diode, a diode bar, an array of laser diodes, an array of diode bars, or one or more vertical cavity surface-emitting lasers (VCSELs). The electrode mounts 110, 115 are thermally connected to the beam emitter 105 and each electrically connected to one of the electrodes (i.e., the anode and the cathode) of the beam emitter 105. For example, the top electrode mount 110 may be electrically connected to the anode of beam emitter 105 and the bottom electrode mount 115 may be electrically connected to the cathode of beam emitter 105, or vice versa. The electrode mounts 110, 115 are typically highly thermally and electrically conductive; thus, in various embodiments, the electrode mounts 110, 115 include, consist essentially of, or consist of one or more metals such as copper, silver, or gold. The electrode mounts 110, 115 may act as heat sinks for the beam emitter 105 (i.e., be in thermal contact therewith and conduct heat away therefrom), and may thus also be referred to as “heat sinks” herein. An insulating layer (not shown) may be disposed around the beam emitter 105 and between the electrode mounts 110, 115, thereby electrically isolating the electrode mounts 110, 115 from each other, and the electrode mounts 110, 115 may be fastened together and to the beam emitter 105 via, e.g., one or more fasteners such as screws, as detailed in U.S. patent application Ser. No. 14/666,438, filed on Mar. 24, 2015, the entire disclosure of which is incorporated by reference herein.

As also shown in FIGS. 1A-1D, the laser assembly 100 also features one or more lenses for the collimation and/or focusing of the beam(s) emitted by the beam emitter 105 (as used herein, “beam” is understood to refer to multiple beams for a beam emitter that emits multiple beams). For example, as shown, the laser assembly 100 may incorporate a fast-axis collimation (FAC) lens 120 and an optical rotator 125 to manipulate the beam emitted by beam emitter 105. As known in the art, laser beams frequently have fast and slow diverging axes, and a FAC lens collimates the fast diverging axis along which the beam rapidly diverges. (Similarly, a slow-axis collimation (SAC) lens collimates the slow diverging axis of the beam.) An optical rotator (or “beam twister” or “optical twister”) typically rotates the beam by approximately 90°, and hence flips the fast and slow diverging axes of the beam. An optical rotator may include or consist essentially of, for example, two cylindrical lenses.

As shown in FIG. 1D, the beam emitter 105 may protrude slightly beyond the edge of the top electrode mount 110 by a distance 130 that may vary along the width of the beam emitter 105 and/or between different laser assemblies 100. Therefore, various embodiments of the present invention mount lenses 120, 125 so that they reliably receive and manipulate the beam from beam emitter 105 via a holder 135 that is mechanically coupled to the bottom electrode mount 115 rather than to the top electrode mount 110. For example, the holder 135 may be fastened to the bottom electrode mount 115 via and adhesive agent such as epoxy. Likewise, the FAC lens 120 and the optical rotator 125 may be coupled to the holder 135 via a fastening agent such as epoxy. As shown in FIG. 1D, the holder 135 may be sized and shaped (e.g., incorporate a step 140) that enables the lenses 120, 125 to be coupled to the holder 135 at desired heights (e.g., relative to beam emitter 105) and distances from each other. The holder 135 may include or consist essentially of, for example, sapphire, quartz, fused silica, crown glass (i.e., glass produced from alkali-lime (RCH) silicates containing approximately 10% potassium oxide), borosilicate glass (e.g., glass containing about 10% boric oxide), or one or more other low-dispersion glasses (e.g., glasses containing zinc oxide, phosphorus pentoxide, barium oxide, fluorite, and/or lanthanum oxide). For example, the holder 135 may include or consist essentially of BK7 optical glass available from SCHOTT North America, Inc. of Elmsford, N.Y. In various embodiments, the coefficient of thermal expansion of the FAC lens 120 (and/or the optical rotator 125) is approximately equal to the coefficient of thermal expansion of the holder 135, thereby minimizing or substantially eliminating relative thermal deformation between the FAC lens 120 (and/or the optical rotator 125) and the holder 135. In various embodiments, the FAC lens 120 (and/or the optical rotator 125) includes or consists essentially of the same material as that of the holder 135.

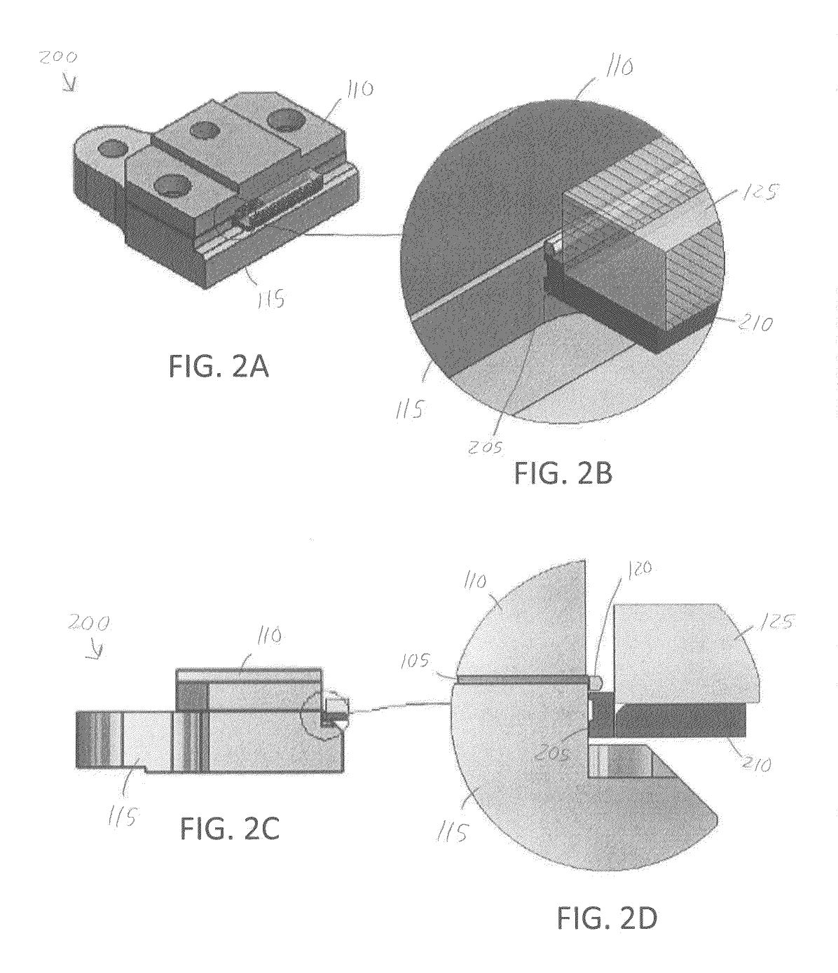

As shown in FIGS. 2A-2D, a one-piece (or “unitary”) holder 135 may be replaced in a laser assembly 200 by a two-piece holder 205, 210. For example, the two-piece holder may include or consist essentially of a first piece 205 that supports the FAC lens 120 and spaces the optical rotator 125 away from the beam emitter 105 (and/or the FAC lens 120) by a desired spacing, as well as a second piece 210 that supports the optical rotator 125. The two pieces 205, 210 may be coupled together permanently or temporarily via, e.g., epoxy. Like holder 135, the two-piece holder 205, 210 may be coupled to the bottom electrode mount 115 via a fastening agent such as epoxy or other adhesive. Also like holder 135, the two-piece holder 205, 210 may include or consist essentially of, for example, sapphire, quartz, fused silica, crown glass, borosilicate glass, or one or more other low-dispersion glasses. For example, one or both pieces of the two-piece holder 205, 210 may include or consist essentially of BK7 optical glass. In various embodiments, the coefficient of thermal expansion of the FAC lens 120 (and/or the optical rotator 125) is approximately equal to the coefficient of thermal expansion of the two-piece holder 205, 210 (or at least first piece 205 thereof), thereby minimizing or substantially eliminating relative thermal deformation between the FAC lens 120 (and/or the optical rotator 125) and the two-piece holder 205, 210 (or at least first piece 205 thereof). In various embodiments, the FAC lens 120 (and/or the optical rotator 125) includes or consists essentially of the same material as that of the two-piece holder 205, 210 (or at least first piece 205 thereof).

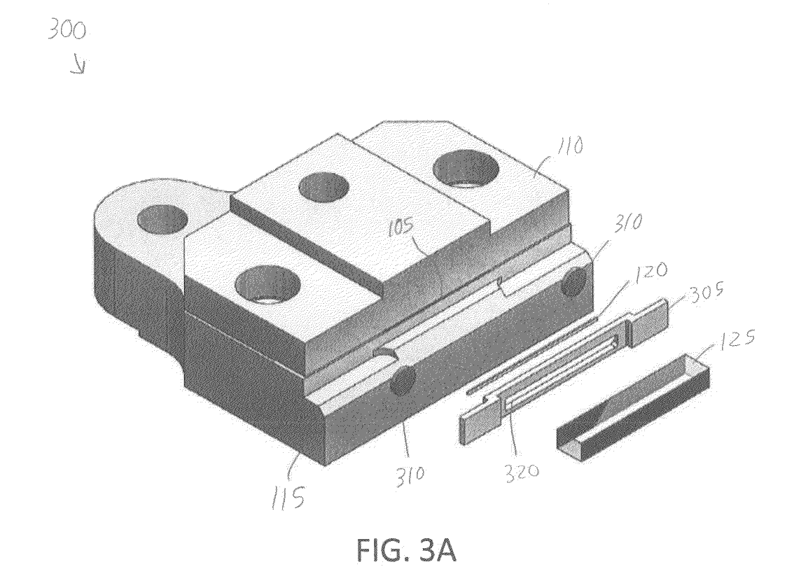

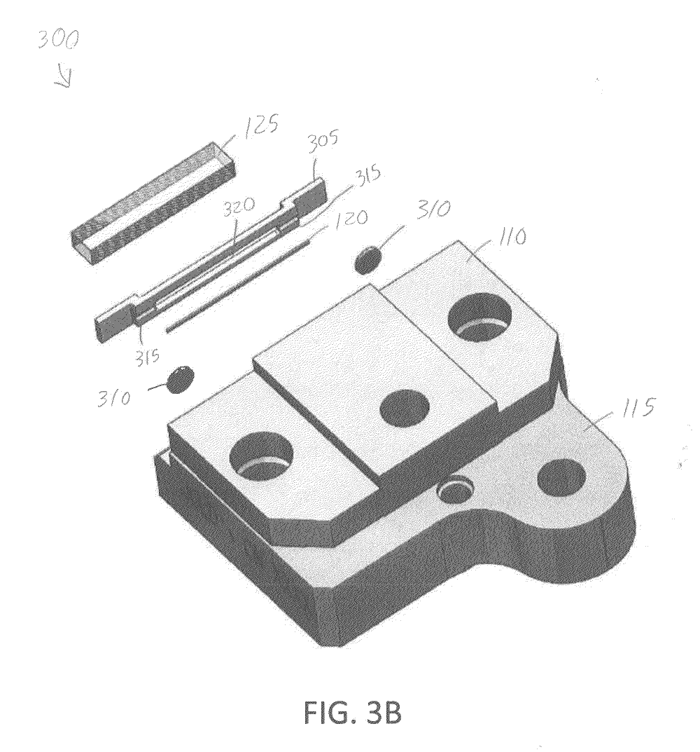

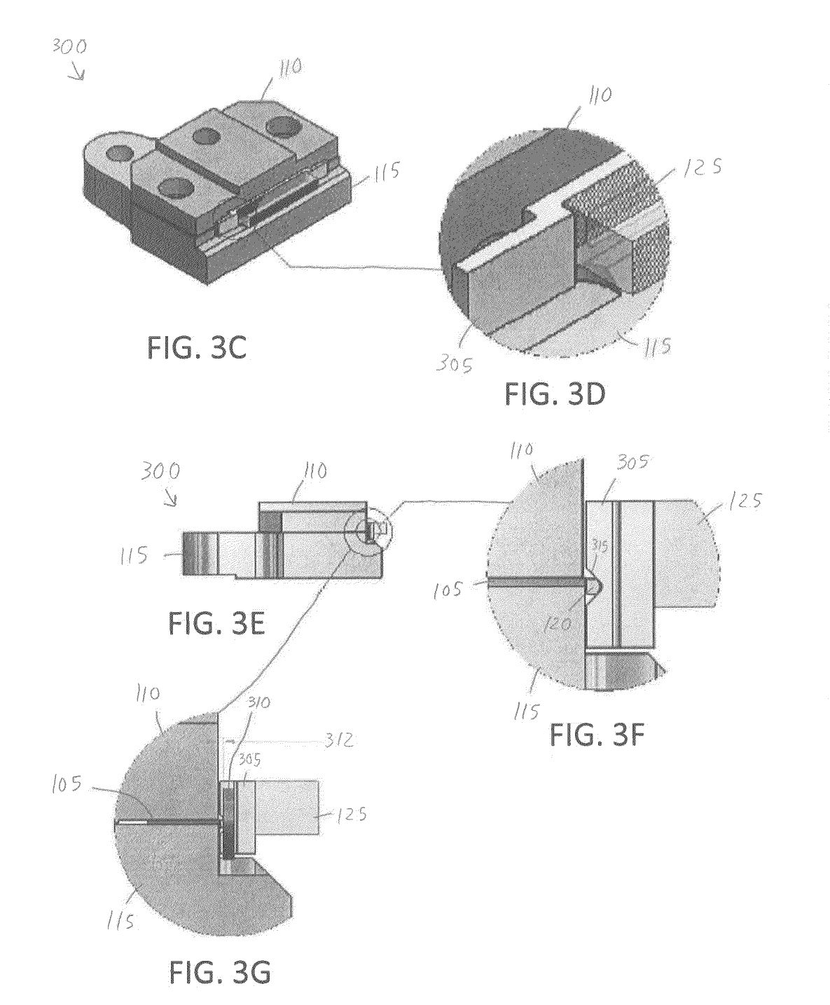

FIGS. 3A-3G depict an exemplary laser assembly 300 in accordance with embodiments of the present invention. In laser assembly 300, the lenses 120, 125 are mounted in front of the beam emitter 105 in a manner such that the attachment points lie approximately along the “neutral axis,” i.e., the axis defined by the beam emitter 105 between the electrode mounts 110, 115. That is, the attachment points are approximately collinear with the beam emitter 105. As shown, in accordance with various embodiments of the invention, the means for mounting the lenses 120, 125 includes or consists essentially of a holder 305 and one or more (or two or more) mounting disks 310. (While in the figures the mounting disks 310 are illustrated as being circular in cross-section, the mounting disks 310 may have any cross-sectional shape.) The holder 305 and/or the mounting disks 310 may include or consist essentially of, for example, sapphire, quartz, fused silica, crown glass, borosilicate glass, or one or more other low-dispersion glasses. For example, holder 305 and/or the mounting disks 310 may include or consist essentially of sapphire, fused silica, and/or BK7 optical glass. In various embodiments, the coefficient of thermal expansion of the FAC lens 120 (and/or the optical rotator 125) is approximately equal to the coefficient of thermal expansion of holder 305 and/or the mounting disks 310, thereby minimizing or substantially eliminating relative thermal deformation between the FAC lens 120 (and/or the optical rotator 125) and the holder 305 and/or the mounting disks 310. In various embodiments, the FAC lens 120 (and/or the optical rotator 125) includes or consists essentially of the same material as that of the holder 305 and/or the mounting disks 310.

As shown in FIGS. 3A-3G, the mounting disks 310 may be coupled (e.g., passively bonded) to both the top electrode mount 110 and the bottom electrode mount 115 via an adhesive agent (e.g., epoxy) that is applied both between each disk 310 and the top electrode mount 110 and each disk 310 and the bottom electrode mount 115. The holder 305 may be a generally elongated part sized and shaped to couple to the disks 310, the FAC lens 120, and the optical rotator 125, as described herein. As shown in the figures, the holder 305 may have two end sections offset from a center section disposed between the end sections. The amount of the offset may be approximately equal to a thickness of the disks 310; that is, when the end sections of the holder 305 are mechanically coupled to the disks 310, the center section of the holder 305 may be substantially in contact with the top electrode mount 110 and/or the bottom electrode mount 115. The center section of the holder 305 may have a width (or other lateral dimension) substantially equal to the width (or other lateral dimension) of the optical rotator 125. The holder 305 may also be coupled to the mounting disks 310 via an adhesive agent (e.g., epoxy). In various embodiments, the only mechanical attachment of holder 305 to the other components of laser assembly 300 (e.g., top electrode mount 110 and bottom electrode mount 115) is via attachment to the mounting disks 310. After bonding of the mounting disks 310 to the electrode mounts 110, 115, the surface of each disk 310 facing the electrode mounts 110, 115 may be spaced away (e.g., via the adhesive agent) from top electrode mount 110 and/or bottom electrode mount 115 by a spacing 312.

As also shown, the FAC lens 120 is supported within the holder 305 at the ends of FAC lens 120. In various embodiments, the ends of FAC lens 120 fit within a groove (e.g., a v-shaped groove) 315 defined by the holder 305. In various embodiments, the FAC lens 120 fits snugly within the groove 315, and between the holder 305 and the beam emitter 105 when the holder is coupled to the electrode mounts 110, 115, and the FAC lens 120 is not otherwise mechanically coupled to holder 305, beam emitter 105, or either electrode mount 110, 115; thus, FAC lens 120 is typically not distorted by shrinkage or expansion of an adhesive agent (e.g., epoxy). In other embodiments, the

FAC lens 120 is attached to the holder 305 via, e.g., an adhesive agent (e.g., epoxy) disposed between the FAC lens 120 and the holder 305 (e.g., within the groove 315). As shown, the holder 305 may also define a slot 320 through which light propagates from the FAC lens 120 to the optical rotator 125. A width (or other lateral dimension) of the slot 320 may be shorter than the corresponding dimension of the optical rotator 125, and those portions of optical rotator 125 extending past the slot 320 may be utilized for mechanical coupling of the optical rotator 125 to the holder 305. For example, an adhesive agent (e.g., epoxy) may be utilized between one or both ends of optical rotator 125 and the portions of holder 305 proximate the slot 320. In various embodiments, the groove 315 and/or the slot 320 may be defined within the holder 305 by cutting techniques such as mechanical machining and/or laser cutting.

In various embodiments of the invention, distortion in (e.g., due to residual stress resulting from fabrication by, for example, molding and dicing) and/or deformation of the FAC lens 120 and/or the optical rotator 125 may be reduced or substantially eliminated by placing the FAC lens 120 and/or the optical rotator 125 into a state of tension during fabrication of laser assembly 300. For example, one or more of the components of laser assembly 300 (e.g., the FAC lens 120, optical rotator 125, holder 305, disks 310, and/or electrode mounts 110, 115) may be heated during the curing of the adhesive agent (e.g. epoxy) that mechanically couples the various components together. The tensile state imposed on FAC lens 120 and/or the optical rotator 125 may prevent the FAC lens 120 and/or the optical rotator 125 from entering a state of compression (with concomitant distortion) during operation and/or temperature changes of laser assembly 300. The tensile state may also substantially remove any distortion of the FAC lens 120 and/or the optical rotator 125 due to residual stress therein from fabrication. Heat may be applied locally (e.g., via a heat gun or other source of heated gas) and/or globally (e.g., by disposing the assembly 300 within an oven or other heat-applying appliance).

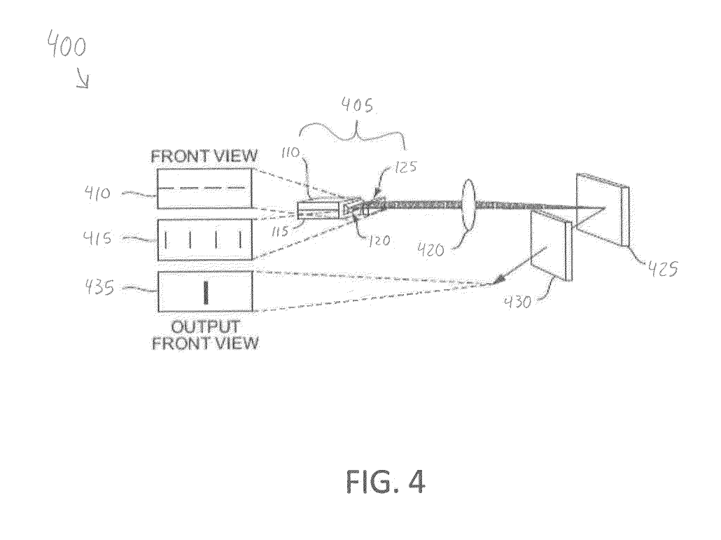

Laser assemblies in accordance with embodiments of the present invention may be utilized in WBC laser systems. FIG. 4 depicts an exemplary WBC laser system 400 that utilizes a laser assembly 405. The laser assembly 405 may correspond to, for example, any of laser assemblies 100, 200, or 300 as detailed herein (holder 135, two-piece holder 205, 210, or holder 305 is not shown in FIG. 4 for clarity). In the example of FIG. 4, laser assembly 405 features a beam emitter (e.g., a diode bar) having four beam emitters each emitting a beam (see magnified input view 410), but embodiments of the invention may utilize beam emitters or diode bars emitting any number of individual beams or two-dimensional arrays or stacks of beam emitters, diodes, or diode bars. In view 410, each beam is indicated by a line, where the length or longer dimension of the line represents the slow diverging dimension of the beam, and the height or shorter dimension represents the fast diverging dimension. FAC lens 120 is used to collimate each beam along the fast dimension. The optical rotator 125 individually rotates the fast and slow dimension of each emitted beam shown in the input front view 410 to produce the re-oriented front view 415. Transform optic(s) 420, which may include or consist essentially of one or more cylindrical or spherical lenses and/or mirrors, are used to combine each beam along a WBC direction. The transform optics 420 overlap the combined beam onto a dispersive element 425 (which may include or consist essentially of, e.g., a reflective or transmissive diffraction grating, a dispersive prism, a grism (prism/grating), a transmission grating, or an Echelle grating), and the combined beam is then transmitted as single output profile onto an output coupler 430. The output coupler 430 then transmits the output beam as shown on the output front view 435. The output coupler 430 is typically partially reflective and acts as a common front facet for all the individual beam emitters (e.g., laser elements) in this external cavity WBC system 400. An external cavity is a lasing system where the secondary mirror is displaced at a distance away from the emission aperture or facet of each laser emitter. In some embodiments, additional optics are placed between the emission aperture or facet and the output coupler or partially reflective surface.

The terms and expressions employed herein are used as terms of description and not of limitation, and there is no intention, in the use of such terms and expressions, of excluding any equivalents of the features shown and described or portions thereof, but it is recognized that various modifications are possible within the scope of the invention claimed.

What is claimed is:

1. A laser assembly comprising:
a beam emitter having (i) top and bottom opposed surfaces and (ii) an emission surface at least partially spanning the top and bottom surfaces;
a top electrode mount disposed above the top surface of the beam emitter;
a bottom electrode mount disposed below the bottom surface of the beam emitter;
a lens mount mechanically coupled to the bottom electrode mount;
a fast axis collimation (FAC) lens disposed on the lens mount and positioned to (i) receive one or more beams emitted by the beam emitter, (ii) collimate the one or more beams, and (iii) transmit the one or more collimated beams; and
an optical rotator disposed on the lens mount and positioned to (i) receive the one or more collimated beams, (ii) rotate the received one or more collimated beams, and (iii) transmit the one or more rotated beams.

2. The laser assembly of claim 1, wherein the beam emitter emits a plurality of beams.

3. The laser assembly of claim 1, wherein the lens mount consists essentially of a unitary structure supporting the FAC lens and the optical rotator.

4. The laser assembly of claim 1, wherein the lens mount comprises a plurality of discrete sections that are mechanically coupled together.

5. The laser assembly of claim 1, wherein the lens mount comprises (i) a first section supporting the FAC lens, and (ii) mechanically coupled to the first section, a second section supporting the optical rotator.

6. The laser assembly of claim 1, wherein a coefficient of thermal expansion of the lens mount is approximately equal to a coefficient of thermal expansion of the FAC lens.

7. The laser assembly of claim 1, wherein the lens mount is mechanically coupled to the bottom electrode mount via an adhesive.

8. The laser assembly of claim 7, wherein the adhesive comprises epoxy.

9. The laser assembly of claim 1, wherein the FAC lens is mechanically coupled to the lens mount via an adhesive.

10. The laser assembly of claim 1, wherein the optical rotator is mechanically coupled to the lens mount via an adhesive.

11. A laser assembly comprising:
a beam emitter having (i) top and bottom opposed surfaces and (ii) an emission surface at least partially spanning the top and bottom surfaces, the beam emitter being configured to emit a plurality of beams;
a top electrode mount disposed above the top surface of the beam emitter;
a bottom electrode mount disposed below the bottom surface of the beam emitter;
a lens mount mechanically coupled to the bottom electrode mount;
a fast axis collimation (FAC) lens disposed on the lens mount and positioned to (i) receive the plurality of beams emitted by the beam emitter, (ii) collimate the plurality of beams, and (iii) transmit the collimated beams; and
an optical rotator disposed on the lens mount and positioned to (i) receive the collimated beams, (ii) rotate the received collimated beams, and (iii) transmit the rotated beams;
focusing optics for focusing the rotated beams onto a dispersive element;
a dispersive element for receiving and dispersing the received focused beams; and
a partially reflective output coupler positioned to receive the dispersed beams, transmit a portion of the dispersed beams therethrough as a multi-wavelength output beam, and reflect a second portion of the dispersed beams back toward the dispersive element.

12. The laser apparatus of claim 11, wherein the dispersive element comprises a diffraction grating.

13. A laser assembly comprising:
a beam emitter having (i) top and bottom opposed surfaces and (ii) an emission surface at least partially spanning the top and bottom surfaces;
a top electrode mount disposed above the top surface of the beam emitter;
a bottom electrode mount disposed below the bottom surface of the beam emitter;
a plurality of mounting disks each mechanically coupled to both the top electrode mount and the bottom electrode mount;
a lens holder (i) defining a slot therethrough and (ii) mechanically coupled to the mounting disks such that the slot is substantially aligned with the emission surface of the beam emitter;
a fast axis collimation (FAC) lens supported by the lens holder and positioned to (i) receive one or more beams emitted by the beam emitter, (ii) collimate the one or more beams, and (iii) transmit the one or more collimated beams; and
an optical rotator supported by the lens holder and positioned to (i) receive the one or more collimated beams, (ii) rotate the received one or more collimated beams, and (iii) transmit the one or more rotated beams.

14. The laser assembly of claim 13, wherein the lens holder has a first surface facing the emission surface of the beam emitter and a second surface opposite the first surface.

15. The laser assembly of claim 14, wherein the first surface of the lens holder defines a groove therewithin.

16. The laser assembly of claim 15, wherein at least a portion of the FAC lens is disposed within the groove.

17. The laser assembly of claim 16, wherein the optical rotator is disposed proximate the second surface of the lens holder.

18. The laser assembly of claim 14, wherein (i) the FAC lens is disposed proximate the first surface of the lens holder and (ii) the optical rotator is disposed proximate the second surface of the lens holder.

19. The laser assembly of claim 13, wherein the beam emitter emits a plurality of beams.

20. The laser assembly of claim 13, wherein a coefficient of thermal expansion of the lens holder is approximately equal to a coefficient of thermal expansion of the FAC lens.

21. The laser assembly of claim 13, wherein the mounting disks are mechanically coupled to the top electrode mount and to the bottom electrode mount via an adhesive.

22. The laser assembly of claim 21, wherein the adhesive comprises epoxy.

23. The laser assembly of claim 13, wherein the FAC lens is mechanically coupled to the lens holder via an adhesive.

24. The laser assembly of claim 13, wherein the FAC lens is supported between the lens holder and the emission surface of the beam emitter without being mechanically coupled to the lens holder or to the emission surface.

25. The laser assembly of claim 13, wherein the optical rotator is mechanically coupled to the lens holder via an adhesive.

26. A laser assembly comprising:
a beam emitter having (i) top and bottom opposed surfaces and (ii) an emission surface at least partially spanning the top and bottom surfaces, the beam emitter being configured to emit a plurality of beams;
a top electrode mount disposed above the top surface of the beam emitter;
a bottom electrode mount disposed below the bottom surface of the beam emitter;
a plurality of mounting disks each mechanically coupled to both the top electrode mount and the bottom electrode mount;
a lens holder (i) defining a slot therethrough and (ii) mechanically coupled to the mounting disks such that the slot is substantially aligned with the emission surface of the beam emitter;
a fast axis collimation (FAC) lens supported by the lens holder and positioned to (i) receive the plurality of beams emitted by the beam emitter, (ii) collimate the plurality of beams, and (iii) transmit the collimated beams; and
an optical rotator supported by the lens holder and positioned to (i) receive the collimated beams, (ii) rotate the received collimated beams, and (iii) transmit the rotated beams;
focusing optics for focusing the rotated beams onto a dispersive element;
a dispersive element for receiving and dispersing the received focused beams; and
a partially reflective output coupler positioned to receive the dispersed beams, transmit a portion of the dispersed beams therethrough as a multi-wavelength output beam, and reflect a second portion of the dispersed beams back toward the dispersive element.

27. The laser apparatus of claim 26, wherein the dispersive element comprises a diffraction grating.
